(19) United States
(12) Patent Application Publication
(10) Pub. No.: US 2023/0260690 A1
(43) Pub. Date: Aug. 17, 2023

(54) Inductor Mountable on a Circuit Board

(71) Applicant: ABB Schweiz AG, Baden (CH)

(72) Inventors: Arturo Silva, Allen, TX (US); Alok K. Lohia, Dallas, TX (US); Robert J. Catalano, Mesquite, TX (US)

(73) Assignee: ABB Schweiz AG, Baden (CH)

(21) Appl. No.: 17/673,163

(22) Filed: Feb. 16, 2022

(51) Int. Cl. H01F 27/29; H05K 1/16; H01F 27/28; H01F 27/30; H02M 3/00; H02M 3/158

(52) U.S. Cl. CPC H01F 27/292; H05K 1/165; H01F 27/2804; H01F 27/306; H02M 3/01; H02M 3/1582; H01F 2027/2814

(57) ABSTRACT

An inductor is disposed above and mounted on a printed wire board. The inductor includes a winding and a core. The winding includes first and second terminations that are electrically connected to the printed wire board at different locations. The core includes: a first section including magnetic material with a channel along an inner surface, to receive the winding, and ending at or above first and second bottom corners of the inner surface; a second section that is a mirror image of the first section including an inner surface that faces the inner surface of the first section; and a distributed gap that uniformly separates the first section from the second section except where the winding passes along the mirror-image channels. The winding lies along the distributed gap in the mirror-image channels, and the winding spatially divides the core into an upper and lower portions of equal volume.

### BACKGROUND

An inductor may be included in a point-of-load (POL) converter, for example, a direct current to direct current (DC-DC) buck converter, a single-phase converter, or a multiphase converter. POL converters may be constructed on a printed wire board and may function as a buck converter or boost converter to step down or up, respectively, an input voltage to a voltage required by a particular load. Loads powered by a POL converter may include fully programmable gate arrays (FPGAs), central processing units (CPUs), digital signal processors (DSPs), application-specific integrated circuits (ASICs), radio frequency (RF) power amplifies (PAs), and the like.

### SUMMARY

One or more embodiments of the present disclosure may provide an inductor configured to be disposed above and mounted on a printed wire board. The inductor may include a winding and a core. The winding may include first and second terminations that are configured to be electrically connected to the printed wire board at different locations. The core may include: a first section including magnetic material with a channel along an inner surface, configured to receive the winding, and ending at or above first and second bottom corners of the inner surface; a second section that is a mirror image of the first section including an inner surface that faces the inner surface of the first section; and a distributed gap that uniformly separates the first section from the second section except where the winding passes along the mirror-image channels. The winding may lie along the distributed gap in the mirror-image channels of the first and second sections, and the winding may spatially divide the core into an upper portion and a lower portion that are equal in volume.

Further, one or more embodiments of the present disclosure may provide a system that includes: a printed wire board; and an inductor disposed above and mounted on the printed wire board. The inductor may include a winding and a core. The winding may include first and second terminations that are configured to be electrically connected to the printed wire board at different locations. The core may include: a first section including magnetic material with a channel along an inner surface, configured to receive the winding, and ending at or above first and second bottom corners of the inner surface; a second section that is a mirror image of the first section including an inner surface that faces the inner surface of the first section; and a distributed gap that uniformly separates the first section from the second section except where the winding passes through the mirror-image channels. The winding may lie along the distributed gap in the mirror-image channels of the first and second sections, and the winding may spatially divide the core into an upper portion and a lower portion that are equal in volume.

### BRIEF DESCRIPTION OF THE DRAWINGS

FIG. 1 shows an electrical circuit diagram of a converter in accordance with one or more embodiments.

FIG. 2A shows a perspective view of an inductor mounted on a printed wire board in accordance with one or more embodiments.

FIG. 2B shows a cross sectional view of FIG. 2A in accordance with one or more embodiments.

FIGS. 2C and 2D show cross sectional views of a termination of a winding of an inductor in a slot in a printed wire board accordance with one or more embodiments.

FIG. 2E shows a cross sectional view of a termination of a winding of an inductor forming a butt joint with the top surface of a printed wire board accordance with one or more embodiments.

FIG. 2F shows a winding of an inductor in accordance with one or more embodiments.

FIGS. 3A and 3B show front and back end views, respectively, of an inductor in accordance with one or more embodiments.

FIGS. 3C-3E show side, bottom, and perspective views of an inductor in accordance with one or more embodiments.

### DETAILED DESCRIPTION

As used herein, a printed circuit board (PCB) refers to a board with the whole circuitry, while a printed wire board (PWB) refers to a board without components. Further, in the present disclosure, up, down, left, right, front, and back, and the like are relative terms.

A POL inductor may be designed to operate in POL converters that carry a few amperes (amps) to hundreds of amps when multiple phases are used. Loads powered by a POL converter may include fully programmable gate arrays (FPGAs), central processing units (CPUs), digital signal processors (DSPs), application-specific integrated circuits (ASICs), radio frequency (RF) power amplifies (PAs), and the like. One or more embodiments of the present disclosure may improve the transient response and the efficiency of the converter. The compact size of the disclosed inductor may increase the power density of each phase. Further, the disclosed inductor may reduce power loss and improve air flow around the inductor and/or other components of the converter.

The inductor may include a core, a winding and a distributed gap for minimizing all related losses such as winding loss, core loss, fringing loss, and the like. Reducing the size of the gap may reduce losses in the core and the winding. In one or more embodiments, the use of two smaller gaps in lieu of a single large gap ground into one of the core legs minimizes the losses. The structure may also reduce coupling between inductors for maximizing performance and maximize air flow. The coupling may be reduced as a factor of the orientation of the inductor based on the location of the gaps. With the gap aligned across the printed wire board, it does not sit next to an adjacent inductor. This greatly reduces, if not eliminate completely, coupling between inductors.

For multiphase converters, in particular, the design of the inductor may be critical for the electrical and thermal performance of the converter on high efficiency applications. The core, the winding, the PWB mounting, as well as inductor coupling may be key elements to consider in optimizing performance. Consideration may be given to the core shape, the winding shape, and assembly techniques that may be fundamental to optimizing a converter.

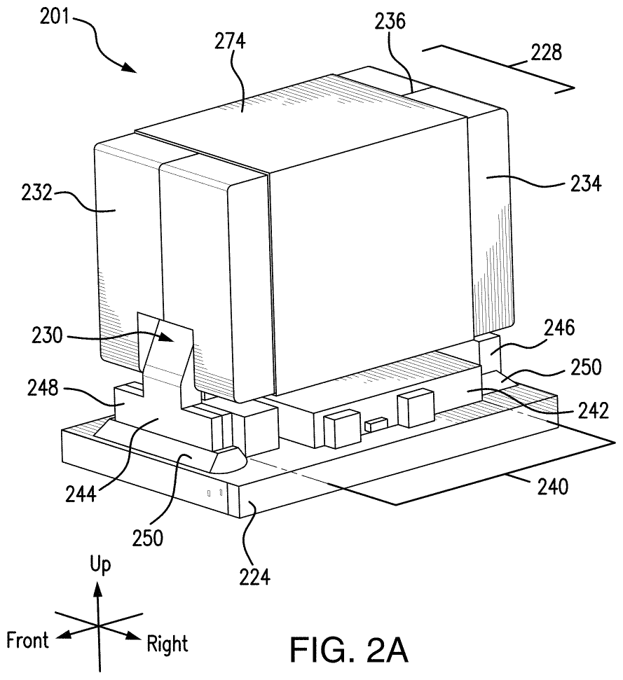

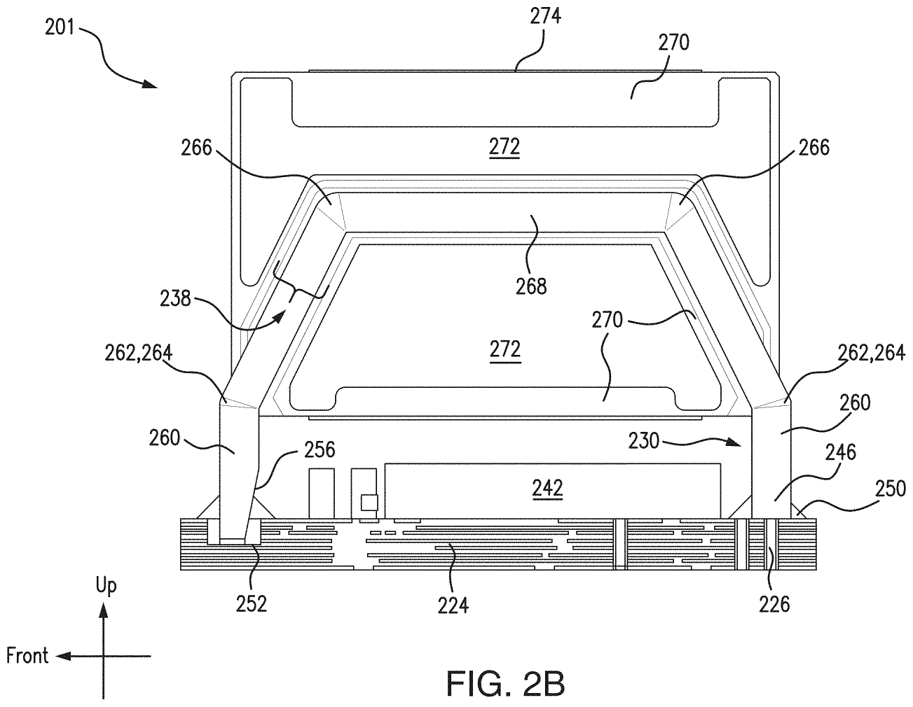

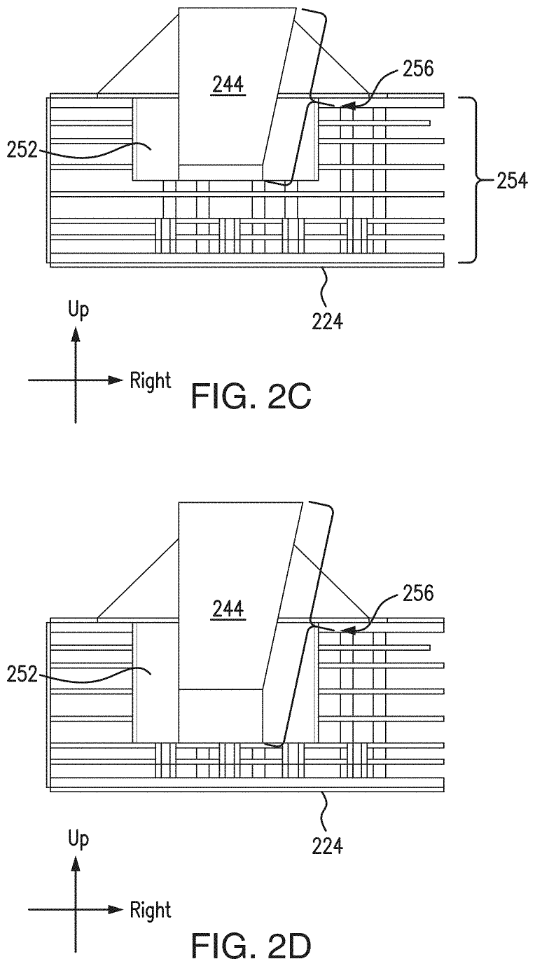

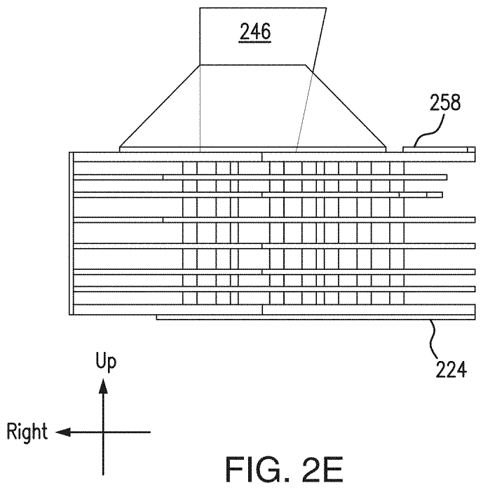

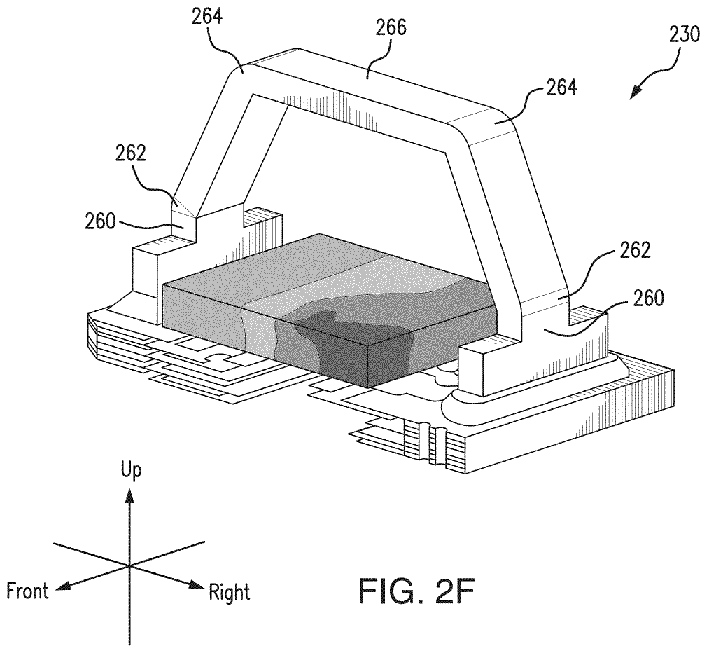

Regarding the winding shape, decreasing the length of the winding may allow reduction in alternating current (AC), current-to-resistance (I2R), and fringing losses. I2R power loss is caused by the flow of current through a resistance. In one or more embodiments, the winding shape may be an A-frame, so called because the shape resembles the lower legs and cross piece of the upper case letter A as seen in FIG. 2B and described in greater detail below.

Regarding the winding landing mechanism on the switch node side of the buck converter, the winding is designed to be surface mounted to the PWB, minimizing the distance between the switch node and the winding. This winding landing mechanism, or winding termination, may reduce loss in the PWB due to the short distance, multiple layers and vias at this location reduces the PWB loss. On the output side of the inductor, the inductor winding is such that goes into a slot in the PWB that also reduces the number of layers in the PWB that the current has to go through.

The winding may also be coined at the end, or termination, of the winding to reduce foot print for improved power density. Coining, as used herein, is a process of flattening. Coining may be a form of precision stamping in which a workpiece is subjected to sufficiently high stress to induce plastic flow on the surface of the material. The plastic flow may reduce surface grain size and work harden the surface. Coining is a cold working process.

The shoulders on the winding side may also reduce losses and increase contact with the PWB in order to reduce loss while improving air flow. The shoulders may further serve as a stop for the inductor to allow for pick and place applications of the module.

In addition, the core shape may be such that the winding enters and exits at angle maximizes the magnetic flux in the core, the top core area and bottom core area being optimized for reduced height and optimized for high flux density application such as high current buck converters. Further, the core may be chamfered on the side to improve the air flow when the inductors are placed side by side.

The inductor core may have a distributed gap located in such a way that reduces magnetic coupling between inductors. Thus, the distributed gap may allow the placement of inductors very close to each other without creating cross talk.

In one or more embodiments, an inductor may be used as part of a converter. Converters may convert alternating current to direct current or vice versa. Further, converters may also be used to step-up (or boost) the input voltage to produce an output voltage that is greater than the input voltage, and converters may be used to step-down (or buck) the input voltage to produce an output voltage that is lower than the input voltage.

In one or more embodiments, the converter may be a non-isolated point-of-load DC-DC step-down converter with an input voltage greater than or equal to 7V and less than or equal to 14 V and an output voltage greater than or equal to 0.45 V and less than or equal to 2 V. A non-isolated converter has a DC path between its input and its output.

The converter may be a multiphase converter that carries up to 40 amperes (A) per phase.

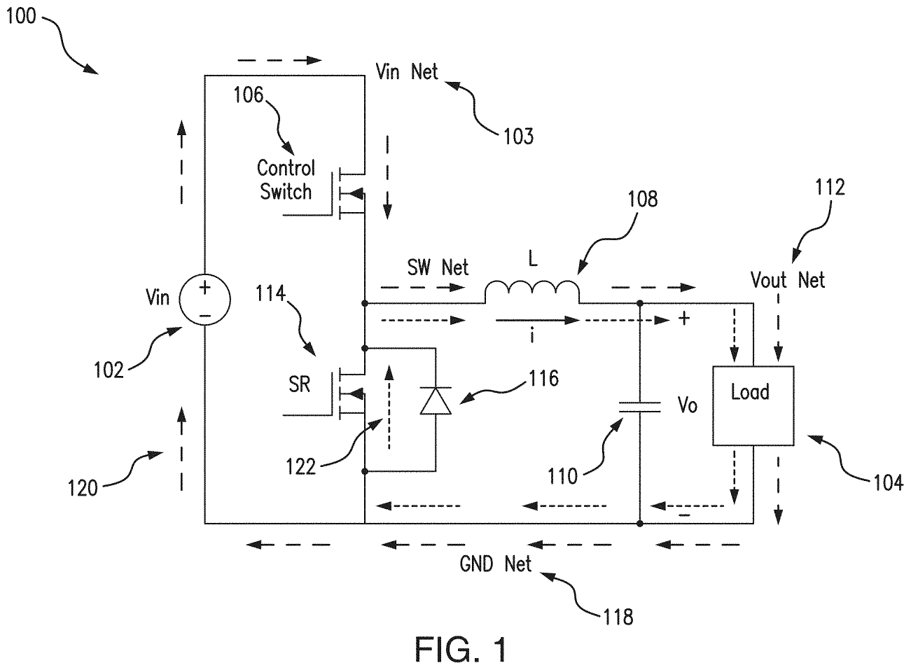

FIG. 1 shows an example electrical circuit diagram of a buck converter 100 with a voltage source 102 that provides an input voltage Vin 103. The voltage source 102 supplies a load 104 via the converter. The converter 100 may include a control switch 106 electrically disposed between the voltage source 102 and an inductor 108. The control switch 106 may include a transistor, for example, a field effect transistor (FET). The output of the inductor 108 may be electrically coupled to the load 104 and a capacitor 110 wired in parallel to the load. The inductor 108 may supply an output voltage Vo 112 from the converter to the load. A set-reset (SR) switch 114 in parallel with a diode 116 may be electrically disposed between ground 118 and the input to load 104. SR switch 114 may be an FET. The long dashed lines 120 represent current flow for the high side printed circuit board (PCB) used to construct the converter 100. Short dashed lines 122 represent current flow for the low side PCB. When the control switch 106 is on, control switch 106 controls one part of the switching network (SW Net, also known as a switching node). When SR switch 114 is on, it controls the other part of the switching network. The switching network SW Net includes the combined effect of both control switch 106 and SR switch 114.

FIG. 2A shows an embodiment of an inductor 201 disposed above and mounted on a printed wire board 224. As seen in the cross sectional view of FIG. 2B, the printed wire board 224 may include multiple layers of conductors and vias 226. Referring again to FIG. 2A, the inductor may include a core 228 and a winding 230.

The core may include a first section 232 and a second section 234 (shown here as the left and right sections, respectively). The first and second sections of the core may be separated by a distributed gap 236. The distributed gap may uniformly separate the first and second sections 232,234 of the core with the exception of a channel 238, as shown in FIG. 2B, provided on an inner surface of each section 232, 234 of the core. In one or more embodiments, the distributed gap 236 may be oriented perpendicularly to the printed wire board. It may be advantageous to have the distributed gap 236 be an air gap, although other types of material may be used in the gap. When the distributed gap 236 is an air gap, the cooling of electronic components 240 disposed on the printed wire board 224 and under the core 228 of the inductor 201 may be improved by permitting increased air circulation. For example, electronic components 240 may include a field effect transistor 242, which may generate large amounts of heat that need to be removed.

Still referring to FIGS. 2A and 2B, the winding 230 may include a first termination 244 and a second termination 246 (shown here as front and back terminations, respectively. The terminations may also be referred to as winding landing mechanisms. The terminations 244, 246 may include shoulders 248 on either side of the winding. The terminations may be electrically connected and mechanically connected to the printed wire board 224 by solder 250.

In one or more embodiments, the first termination 244 of the winding 230 may be disposed in a slot 252 on the printed wire board 224 as seen in FIG. 2B. FIGS. 2C and 2D show a cross sectional view of first termination 244 of the inductor winding 230 in slots 252 of different depths in a printed wire board 224. The printed wire board includes multiple layers 254. Shoulders 248 ensure that the first termination drops to the correct depth into the slot 252.

In one or more embodiments, one or both of the winding terminations 244, 246 may be coined 256. Coining may be used to reduce the footprint of the terminations as well as to increase the power density.

The second termination 246 may be on the control switch 106 side of inductor 108 in a buck converter 100. As shown in FIG. 2E, the second termination 246 may form a butt joint with the top surface 258 of the printed wire board 224.

Referring again to FIGS. 2A and 2B, winding 230 may be disposed in channels 238, which are created on the facing inner surfaces of the left and right sections 232, 234 of the core 228. The winding may be an electrical conductor such as stamped copper, though other electrically conductive material may be used. FIG. 2F shows a perspective view of a winding 230. Aside from differences in the terminations, the winding 230 may possess a left-right symmetry as well as a front-back symmetry. Referring to both FIGS. 2B and 2F, the winding 230 may have vertical portions 260 extending up from the terminations. These vertical portions may be used to elevate the inductor core above the printed wire board, allowing clearance for components to be disposed on the printed wire board below the core and for air flow around the components for cooling.

The winding 230 may run along the distributed gap by following the channels in the left and right sections of the core. The mirror-image channels that hold the winding 230 may end at the bottom corners 262 of the inner surfaces where the mirror-image channels bend by a first angle 264 between 0 and 90 degrees and bend a second time by a second angle 266 that is the complement of the first angle resulting in a horizontal portion 268 of the mirror-image channels, and consequently, the winding 230. (Mirror-image used herein refers to properties of symmetry and not to optically or electromagnetically reflective surfaces.) Because the winding follows the channels, the winding may have the same shape. This shape may be referred to as an A-frame shape because the winding resembles the lower legs and the cross piece of the upper case letter A. The A-frame shape may be advantageous by reducing the length of the winding 230, thus reducing losses. Further, by entering the core 228 at the core's lower edges, a greater portion of magnetic flux is kept within the cure, helping to reduce the size of the core.

Referring again to FIG. 2B, the winding 230 may spatially divide the core 228 into an upper portion and a lower portion. The upper and lower portions of the core 228 may be equal in volume and have equal magnetic flux density. The core 228 may include a magnetic material 270 with a magnetic permeability greater than a magnetic permeability of free space. An example of such material may be ferrite, perhaps manganese-zinc (MnZn) ferrite. The core 228 may also include one or more regions of a nonmagnetic spacer 272. This spacer 272 may be used to tune the inductance of the inductor 201. The one or more spacers may include an aromatic polyamide polymer. For example, the spacers may include a poly (m-phenylenediamine isophthalamide) paper, such as the commercially available Nomex® paper.

As shown in FIGS. 2A and 2B, the inductor 201 may include a wrap 274 disposed around the core 228 that fixes the relative positions of the winding 230 and the first and second sections 232,234 of the core. The wrap may be, for example, an adhesive tape.

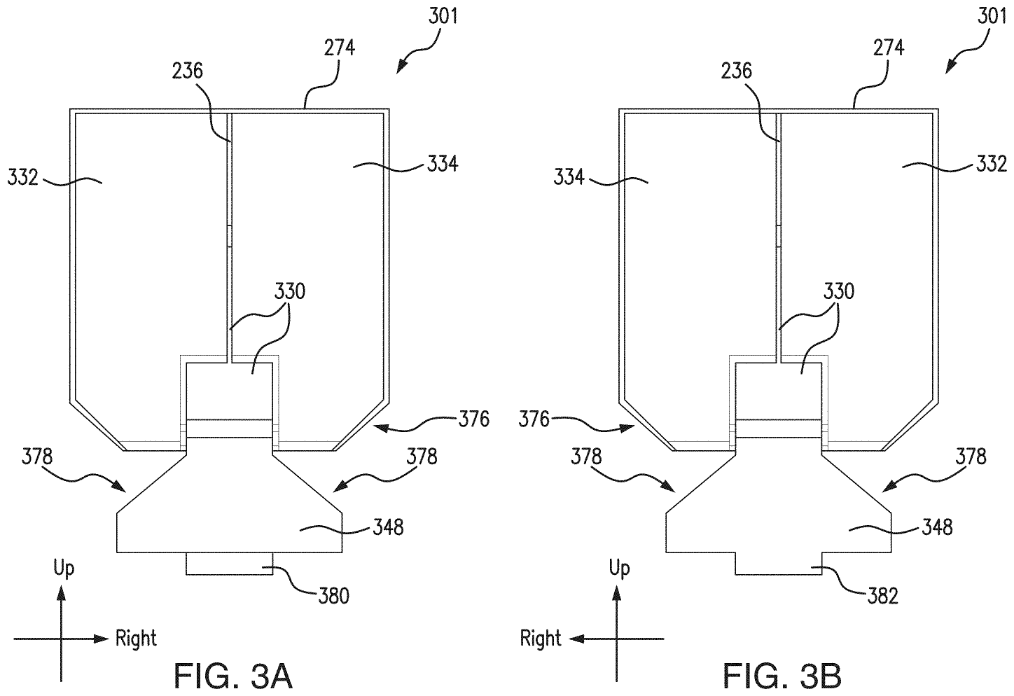

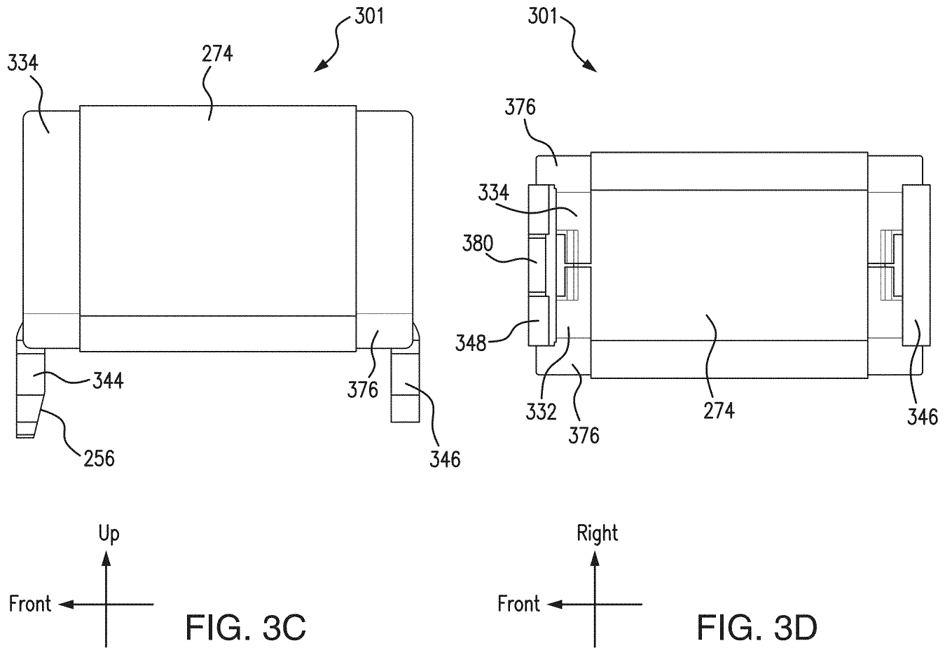

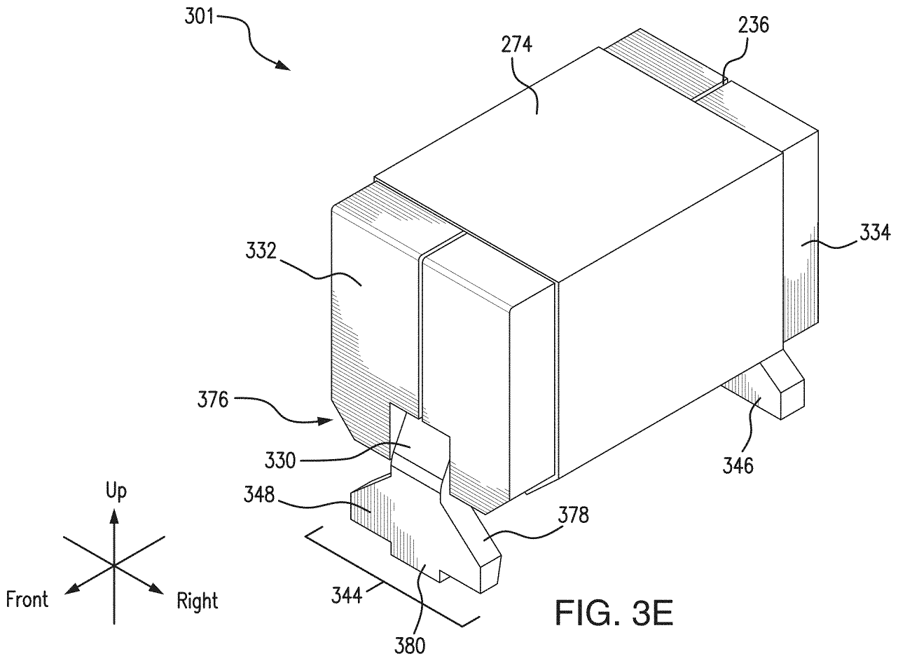

FIGS. 3A-3E show various views of an inductor with many features similar to those already discussed above. The inductor 301 that includes a winding 330 and first and second sections 332, 334 of a core. The core is chamfered 376 on its left bottom and right bottom edges. This chamfering may improve airflow under the core, providing additional cooling to electronic components that may be disposed below the inductor's core sections 332, 334.

The winding 330 may include terminations 344, 346 that have shoulders 348. In one or more embodiments, the first and second terminations 344, 346 each include a pair of shoulders 348 that extend outward from the winding 330 in opposite directions. The shoulders 348 may slope downward while extending outward 378.

Terminations 344, 346 may form a butt joint with a printed wire board. However, one or both terminations may include a tab 380, 382 that inserts into a slot in the printed wire board.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. An inductor configured to be disposed above and mounted on a printed wire board, the inductor comprising:
a winding, comprising:
first and second terminations that are configured to be electrically connected to the printed wire board at different locations; and
a core, comprising:
a first section comprising magnetic material with a channel along an inner surface, configured to receive the winding, and ending at or above first and second bottom corners of the inner surface;
a second section that is a mirror image of the first section including an inner surface that faces the inner surface of the first section; and
a distributed gap that uniformly separates the first section from the second section except where the winding passes along the mirror-image channels,
wherein:
the winding lies along the distributed gap in the mirror-image channels of the first and second sections, and
the winding spatially divides the core into an upper portion and a lower portion that are equal in volume.

2. The inductor of claim 1, wherein the mirror-image channels that hold the winding end at the first and second bottom corners of the inner surfaces where the mirror-image channels bend by a first angle between 0 and 90 degrees and bend a second time by a second angle that is the complement of the first angle resulting in a horizontal portion of the mirror-image channels.

3. The inductor of claim 2, wherein the winding extends vertically downward from the first and second bottom corners.

4. The inductor of claim 1, wherein:
the first termination terminates in a slot in the printed wire board, and
the second termination terminates on a top surface of the printed wire board.

5. The inductor of claim 4, wherein the first and second terminations are coined.

6. The inductor of claim 1, wherein the inductor further comprises a wrap disposed around the core that fixes relative positions of the winding and the first and second sections of the core.

7. The inductor of claim 1, wherein the distributed gap is oriented perpendicularly to the printed wire board.

8. The inductor of claim 1, wherein the core further comprises at least one region of a nonmagnetic spacer.

9. The inductor of claim 8, wherein the nonmagnetic spacer comprises aromatic polyamide polymer.

10. The inductor of claim 9, wherein the nonmagnetic spacer comprises poly (m-phenylenediamine isophthalamide) paper.

11. A system comprising:
a printed wire board; and
an inductor disposed above and mounted on the printed wire board, the inductor comprising:
a winding, comprising:
first and second terminations that are configured to be electrically connected to the printed wire board at different locations; and
a core, comprising:
a first section comprising magnetic material with a channel along an inner surface, configured to receive the winding, and ending at or above first and second bottom corners of the inner surface;
a second section that is a mirror image of the first section including an inner surface that faces the inner surface of the first section; and
a distributed gap that uniformly separates the first section from the second section except where the winding passes through the mirror-image channels,
wherein:
the winding lies along the distributed gap in the mirror-image channels of the first and second sections, and
the winding spatially divides the core into an upper portion and a lower portion that are equal in volume.

12. The system of claim 11, wherein the mirror-image channels that hold the winding end at the first and second bottom corners of the inner surfaces where the mirror-image channels bend by a first angle between 0 and 90 degrees and bend a second time by a second angle that is the complement of the first angle resulting in a horizontal portion of the mirror-image channels.

13. The system of claim 12, wherein the winding extends vertically downward from the first and second bottom corners.

14. The system of claim 11, the system further comprising a converter that converts an input voltage to an output voltage that is different from the input voltage.

15. The system of claim 14, wherein the converter is a direct current to direct current converter that converts the input voltage to the output voltage that is less than the input voltage.

16. The system of claim 15, wherein:
the first and second terminations each comprise a pair of shoulders that extend outward from the winding in opposite directions,
the first termination terminates in a slot in the printed wire board, and
the second termination terminates on a top surface of the printed wire board.

17. The system of claim 16, wherein:
the first and second terminations are coined, and
the shoulders slope downward while extending outward.

18. The system of claim 16, wherein the second termination is disposed on a switch node side of the converter.

19. The system of claim 13, wherein both the first section and the second section of the core comprise a chamfered lower outward edge parallel to the horizontal portion of the mirror-image channels.

20. The system of claim 11, wherein the distributed gap is oriented perpendicularly to the printed wire board.

21. The system of claim 11, wherein the core further comprises at least one region of a nonmagnetic spacer.

22. The system of claim 21, wherein the nonmagnetic spacer comprises an aromatic polyamide polymer.

23. The system of claim 22 wherein the nonmagnetic spacer comprises poly (m-phenylenediamine isophthalamide) paper.

24. The system of claim 14, wherein the converter comprises a non-isolated point-of-load DC-DC step-down converter with the input voltage greater than or equal to 7V and less than or equal to 14 V and the output voltage greater than or equal to 0.45 V and less than or equal to 2 V.

25. The system of claim 24, wherein the converter is configured to carry up to 40 amperes per phase.
